(19) United States
(12) Patent Application Publication
(10) Pub. No.: US 2024/0203922 A1
(43) Pub. Date: Jun. 20, 2024

(54) SEMICONDUCTOR PACKAGING METHOD AND SEMICONDUCTOR PACKAGING STRUCTURE

(71) Applicant: SiPLP Microelectronics (Chongqing) Limited, Chongqing (CN)

(72) Inventor: Weiyuan YANG, Chongqing (CN)

(21) Appl. No.: 18/260,922

(22) PCT Filed: Mar. 29, 2022
(86) PCT No.: PCT/CN2022/083631

§ 371 Date: Sep. 11, 2023

(30) Foreign Application Priority Data
Mar. 31, 2021 (CN) 202110352203.7

(51) Int. Cl. H01L 23/00; H01L 21/56; H01L 23/31

(52) U.S. Cl. CPC H01L 24/19; H01L 21/568; H01L 24/20; H01L 23/3135; H01L 2224/19; H01L 2224/2105; H01L 2224/211; H01L 2224/215; H01L 2224/221

(57) ABSTRACT

A semiconductor packaging method and a semiconductor packaging structure are provided. The semiconductor packaging method includes: providing a chip; forming a first encapsulation layer surrounding the chip; forming an embedded wiring layer at least on a side of the first encapsulation layer; forming a second encapsulation layer covering the first encapsulation layer and the embedded wiring layer, where an accommodation cavity is formed in a region of the second encapsulation layer corresponding to the chip; forming a fan-out wiring layer on a surface of the first encapsulation layer away from the second encapsulation layer, where the fan-out wiring layer is electrically connected to the embedded wiring layer and a pin of the chip.

### TECHNICAL FIELD

The present disclosure relates to the field of semiconductor technologies, and in particular to a semiconductor packaging method and a semiconductor packaging structure.

### BACKGROUND

Along with fast development of scientific technologies, semiconductor devices are applied more and more widely in the social production and living. At present, a chip is usually packaged to form a packaging structure. However, since the existing packaging structure has excessively large wiring density, the packaging process difficulty is increased.

### SUMMARY

An object of the present disclosure is to provide a semiconductor packaging method and a semiconductor packaging structure so as to solve the problem of high packaging process difficulty resulting from high wiring density.

According to one aspect of the present disclosure, there is provided a semiconductor packaging method, including:
providing a chip;
forming a first encapsulation layer surrounding the chip;
forming an embedded wiring layer at least on a side of the first encapsulation layer;
forming a second encapsulation layer covering the first encapsulation layer and the embedded wiring layer, where an accommodation cavity is formed in a region of the second encapsulation layer corresponding to the chip; and
forming a fan-out wiring layer on a surface of the first encapsulation layer away from the second encapsulation layer, where the fan-out wiring layer is electrically connected to the embedded wiring layer and a pin of the chip.

In an embodiment, forming the first encapsulation layer surrounding the chip includes:
providing a carrier plate, forming the first encapsulation layer on the carrier plate, and attaching the chip onto the first encapsulation layer, where the first encapsulation layer surrounds the chip and a back surface of the chip is away from the carrier plate;
forming the embedded wiring layer at least on a side of the first encapsulation layer includes:
forming the embedded wiring layer at least on a side of the first encapsulation layer away from the carrier plate;
forming the fan-out wiring layer on the surface of the first encapsulation layer away from the second encapsulation layer includes:
removing the carrier plate, and forming the fan-out wiring layer on the surface of the first encapsulation layer away from the second encapsulation layer.

In an embodiment, the pin of the chip includes a first pin and a second pin, the embedded wiring layer includes an embedded line, and the fan-out wiring layer includes:
a first fan-out line, electrically connected to the embedded line and the first pin of the chip; and
a second fan-out line, insulated from the first fan-out line and electrically connected to the second pin of the chip.

In an embodiment, forming the embedded wiring layer at least on a side of the first encapsulation layer includes:
forming a plurality of via-holes in the first encapsulation layer, and forming the embedded wiring layer at a side of the first encapsulation layer and in the via-holes; or,
forming a recess in the first encapsulation layer, forming a plurality of via-holes in a bottom wall of the recess, and forming the embedded wiring layer in the recess and the via-holes to fill the recess and the via-holes; or,
forming a recess in the first encapsulation layer, forming a plurality of via-holes in a bottom wall of the recess, forming a stepped structure on a sidewall of the recess, and forming the embedded wiring layer in the recess and the via-holes to cover the bottom wall of the recess and fill the via-holes.

In an embodiment, the fan-out wiring layer further includes:
a third fan-out line, disposed on a surface of the first encapsulation layer away from the second encapsulation layer and electrically connected to the embedded line;
the semiconductor packaging method further includes:
forming a conductive column layer, where the conductive column layer includes a first conductive column and a second conductive column, the first conductive column is disposed on a surface of the third fan-out line away from the second encapsulation layer and electrically connected to the third fan-out line, and the second conductive column is disposed on a surface of the second fan-out line away from the second encapsulation layer and electrically connected to the second fan-out line; and
forming a dielectric layer covering the fan-out wiring layer and the first encapsulation layer, where the dielectric layer surrounds the first conductive column and the second conductive column.

In an embodiment, forming the first encapsulation layer surrounding the chip includes:
forming the first encapsulation layer; forming a first window in the first encapsulation layer; and disposing the chip in the first window.

According to one aspect of the present disclosure, there is provided a semiconductor packaging structure, including:
a chip;
a packaging body, packaging the chip and including a first encapsulation layer and a second encapsulation layer stacked;
an embedded wiring layer, disposed between the first encapsulation layer and the second encapsulation layer; and
a fan-out wiring layer, disposed on a surface of the first encapsulation layer away from the second encapsulation layer, and electrically connected to the embedded wiring layer and a pin of the chip.

In an embodiment, an accommodation cavity is disposed on a surface of the second encapsulation layer facing toward the first encapsulation layer;

the chip is disposed in the accommodation cavity, and a front surface of the chip is away from the accommodation cavity and located outside the accommodation cavity; and

the embedded wiring layer is disposed in a region outside the accommodation cavity.

In an embodiment, the pin of the chip includes a first pin and a second pin, the embedded wiring layer includes an embedded line, and the fan-out wiring layer includes:
a first fan-out line, electrically connected to the embedded line and the first pin of the chip; and
a second fan-out line, insulated from the first fan-out line and electrically connected to the second pin of the chip.

In an embodiment, the semiconductor packaging structure further includes:
a dielectric layer, disposed at a side of the first encapsulation layer away from the second encapsulation layer, and covering the fan-out wiring layer; and
a conductive column layer, at least partially formed in the dielectric layer, where the conductive column layer includes a first conductive column and a second conductive column, the first conductive column is electrically connected to the embedded line, and the second conductive column is electrically connected to the second fan-out line.

In an embodiment, a plurality of via-holes are provided in the first encapsulation layer, and the embedded wiring layer fills the via-holes; or,
a recess is provided in the first encapsulation layer, a plurality of via-holes are provided in a bottom wall of the recess, and the embedded wiring layer is formed in the recess and the via-holes to fill the recess and the via-holes; or,
a recess is provided in the first encapsulation layer, a plurality of via-holes are provided in a bottom wall of the recess, and a stepped structure is provided in a sidewall of the recess; the embedded wiring layer is formed in the recess and the via-holes to cover the bottom wall of the recess and fill the via-holes.

In an embodiment, a material of the first encapsulation layer includes a photosensitive material.

### BRIEF DESCRIPTION OF THE DRAWINGS

FIG. 1 is a schematic diagram illustrating a section of a chip according to an embodiment of the present disclosure.

FIG. 2 is a schematic diagram illustrating a chip at another view angle according to an embodiment of the present disclosure.

FIG. 3 is a flowchart illustrating a semiconductor packaging method according to an embodiment of the present disclosure.

FIG. 4 is a schematic diagram illustrating a structure after forming a first encapsulation layer according to an embodiment of the present disclosure.

FIG. 5 is a schematic diagram illustrating a structure after forming an embedded wiring layer in the semiconductor packaging method according to an embodiment of the present disclosure.

FIG. 6 is a schematic diagram illustrating a structure after attaching a chip in the semiconductor packaging method according to an embodiment of the present disclosure.

FIG. 7 is another schematic diagram illustrating a structure after forming an embedded wiring layer in the semiconductor packaging method according to an embodiment of the present disclosure.

FIG. 8 is a schematic diagram illustrating a structure after forming a photoresist layer in the semiconductor packaging method according to an embodiment of the present disclosure.

FIG. 9 is yet another schematic diagram illustrating a structure after forming an embedded wiring layer in the semiconductor packaging method according to an embodiment of the present disclosure.

FIG. 10 is a schematic diagram illustrating a structure after forming a second encapsulation layer in the semiconductor packaging method according to an embodiment of the present disclosure.

FIG. 11 is a schematic diagram illustrating a structure after removing a carrier plate in the semiconductor packaging method according to an embodiment of the present disclosure.

FIG. 12 is a schematic diagram illustrating a structure after forming a fan-out wiring layer in the semiconductor packaging method according to an embodiment of the present disclosure.

FIG. 13 is a schematic diagram illustrating a structure after forming a dielectric layer in the semiconductor packaging method according to an embodiment of the present disclosure.

FIGS. 14 to 16 are sectional diagrams taken along an A-A line of the structure shown in FIG. 13.

Numerals of the drawings are described below: 1. chip; 2. pin; 201. first pin; 202. second pin; 3. fan-out wiring layer; 301. first fan-out line; 302. second fan-out line; 303. third fan-out line; 4. embedded wiring layer; 401. embedded line; 5. first conductive column; 6. second conductive column; 7. second encapsulation layer; 8. first encapsulation layer; 9. dielectric layer; 10. Recess; 11. via-hole; 12. protective layer; 13. carrier plate; 14. adhesive layer; 15. stepped structure; 16. photoresist layer.

### DETAILED DESCRIPTION

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

Terms used herein are used to only describe a particular embodiment rather than limit the present disclosure. Unless otherwise defined, technical terms or scientific terms used in the present disclosure should have general meanings that can be understood by those skilled in the art. “First”, “second” and the like used in the specification and claims do not represent any sequence, quantity or importance, but distinguish different components. Similarly, “a” or “an” and the like do not represent quantity limitation but represent at least one. “Multiple” or “a plurality” represents two or more. Unless otherwise stated, the words such as “front”, “rear”, “lower” and/or “upper” are used only for ease of descriptions rather than limited to one position or a spatial orientation. Unless otherwise stated, “include” or “comprise” or the like is intended to refer to that an element or object appearing before “include” or “comprise” covers an element or object or its equivalents listed after “include” or “contain” and does not preclude other elements or objects. “Connect” or “connect with” or the like is not limited to physical or mechanical connection but includes direct or indirect electrical connection. The singular forms such as “a”, “said”, and “the” used in the present disclosure and the appended claims are also intended to include plural forms, unless the context clearly indicates otherwise. It is also to be understood that the term “and/or” as used herein refers to and includes any or all possible combinations of one or more associated listed items.

An embodiment of the present disclosure provides a semiconductor packaging method, which may include: providing a chip; forming a first encapsulation layer around the chip; forming an embedded wiring layer at least on a side of the first encapsulation layer; forming a second encapsulation layer covering the first encapsulation layer and the embedded wiring layer, where an accommodation cavity is formed in a region of the second encapsulation layer corresponding to the chip; and forming a fan-out wiring layer at a side of the first encapsulation layer away from the second encapsulation layer, where the fan-out wiring layer is electrically connected to the embedded wiring layer and a pin of the chip.

In the semiconductor packaging method of the embodiments of the present disclosure, the embedded wiring layer is disposed between the second encapsulation layer and the first encapsulation layer, and the fan-out wiring layer is disposed on a surface of the first encapsulation layer away from the second encapsulation layer. In this way, a wiring density of the second encapsulation layer is reduced, and further, the problem of high process difficulty resulting from high wiring density can be solved.

The parts of the semiconductor packaging method of the embodiments of the present disclosure will be detailed below.

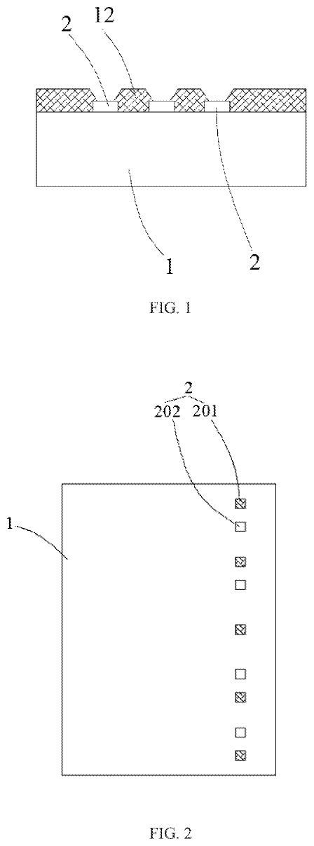

The chip include a front surface, a back surface and a side surface, where the front surface and the back surface are opposed to each other and the side surface of the chip is connected between the front surface and the back surface. As shown in FIG. 1, the front surface of the chip 1 may be provided with a pin 2, and the pin 2 may be plural in number. For example, as shown in FIG. 2, the chip 1 may include a plurality of first pins 201 and a plurality of second pins 202, where the first pins 201 and the second pins 202 are spaced apart. A plurality of first pins 201 and a plurality of second pins 202 are distributed along a preset direction to form a pin column. As shown in FIG. 1, the front surface of the chip 1 may also be provided with a protective layer 12, which covers the front surface of the chip 1. Via-holes are disposed in a region of the protective layer 12 corresponding to the pins 2. A material of the protective layer 12 may be resin or the like.

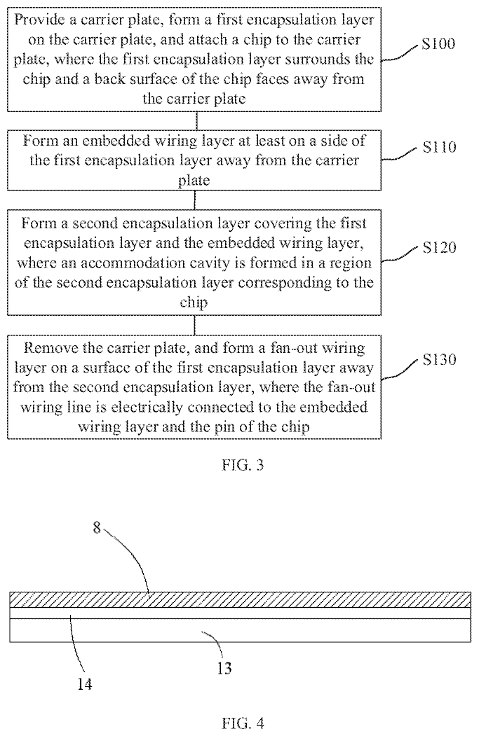

In an embodiment of the present disclosure, as shown in FIG. 3, forming the first encapsulation layer as above may include step S100, forming the embedded wiring layer as above may include step S110, and forming the fan-out wiring layer as above may include step S130.

At step S100, a carrier plate is provided, and a first encapsulation layer is formed on the carrier plate and a chip is attached to the carrier plate, where the first encapsulation layer surrounds the chip and a back surface of the chip is away from the carrier plate.

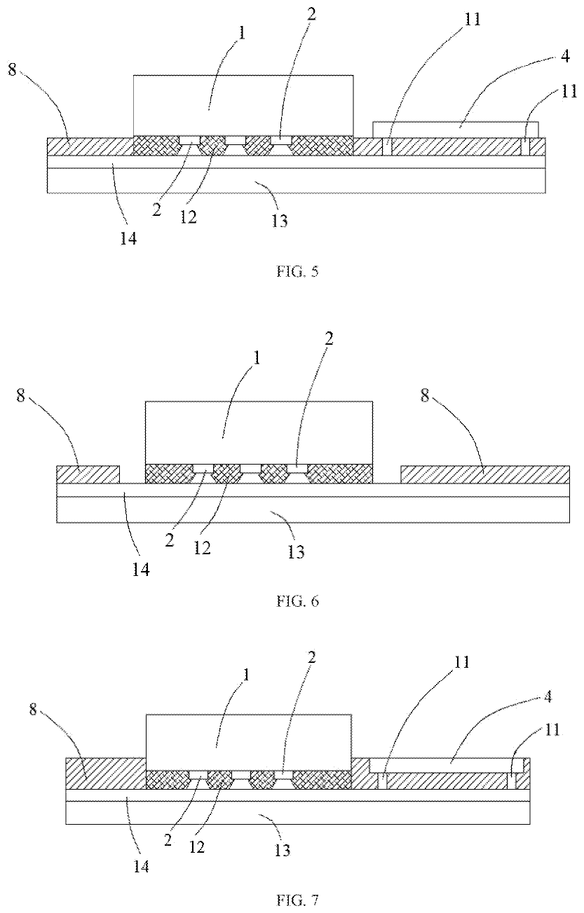

As shown in FIGS. 4 and 5, in the present disclosure, the chip 1 may be attached after the first encapsulation layer 8 is formed. The process specifically includes: forming the first encapsulation layer 8 on the carrier plate 13; patterning the first encapsulation layer 8 to form a first window in the first encapsulation layer 8; and attaching the chip 1 to the carrier plate 13 through the first window. As shown in FIG. 6, a gap may also be present between a sidewall of the first window and the chip 1. The chip 1 is disposed in the first window, such that a displacement amount of the chip 1 during a subsequent packaging process can be effectively reduced. The material of the first encapsulation layer 8 may be an insulation material. Furthermore, the material of the first encapsulation layer 8 may be a photosensitive material. For example, the material of the first encapsulation layer 8 may be solder mask, polyimide, photo imageable dielectric (PID) or the like. In addition, an adhesive layer 14 may be provided between the first encapsulation layer 8 and the carrier plate 13.

An embedding region spaced apart from the first window may be further disposed on the first encapsulation layer 8. When the first encapsulation layer 8 is patterned, a plurality of via-hole groups may be formed in the embedding region in the present disclosure. A number of the via-hole groups is equal to the number of the first pins 201 on the chip 1, and a plurality of via-hole groups are in one-to-one correspondence with a plurality of first pins 201. As shown in FIG. 5, each via-hole group includes a plurality of via-holes 11. For example, each via-hole group includes two via-holes 11. Furthermore, as shown in FIG. 7, a recess 10 is firstly formed in the embedding region of the first encapsulation layer 8 in the present disclosure (see FIG. 8), a plurality of via-hole groups are formed in a bottom wall of the recess 10, and an embedded wiring layer 4 formed subsequently may be disposed in the recess 10. As shown in FIGS. 8 and 9, a sidewall of the recess 10 may be formed into a stepped stair structure 15, which is applicable to preparation of smaller via-holes 11 and further makes smaller a line width and a line distance of an embedded line 401 (see FIG. 13) subsequently formed. In this way, the lines can be further refined. Therefore, further miniaturization of the packaging products can be achieved. The stepped stair structure 15 may be formed by laser drilling, laser cutting and laser imaging etc. Specifically, in the present disclosure, the stepped stair structure 15 may be formed by controlling laser imaging energy, which is not limited to one of the methods and thus can be formed by combination of several methods. In other embodiments of the present disclosure, the stepped stair structure 15 may also be formed in a grayscale exposure process.

At step S110, an embedded wiring layer is formed at least on a side of the first encapsulation layer away from the carrier plate.

As shown in FIG. 5, the embedded wiring layer 4 may be manufactured by electroplating process. The embedded wiring layer 4 may include an embedded line 401 (see FIG. 13). The embedded line 401 may be plural in number, and a plurality of embedded lines 401 are spaced apart, and the plurality of embedded lines 401 are in one-to-one correspondence with the plurality of via-hole groups. During the formation of the embedded wiring layer 4, the embedded lines 401 may fill a plurality of via-holes in the corresponding via-hole groups. For example, when the recess 10 is formed in the first encapsulation layer 8, the step 110 may include: forming the embedded wiring layer 4 in the recess 10 and the via-holes 11 to fill the recess 10 and the via-holes 11, where the structure after forming the embedded wiring layer 4 is as shown in FIG. 7. For example, when the recess 10 is formed in the first encapsulation layer 8 and the stepped stair structure 15 is formed on the sidewall of the recess 10, the step 110 may include: forming the embedded wiring layer 4 in the recess 10 and the via-holes 11 to cover the bottom wall of the recess 10 and fill the via-holes 11, where the structure after forming the embedded wiring layer 4 is as shown in FIG. 9. Furthermore, as shown in FIGS. 8 and 9, in the present disclosure, before electroplating is performed, a photoresist layer 16 covering the first encapsulation layer 8 may be formed and then patterned to form a second window in a region of the photoresist layer 16 corresponding to the above embedding region. The embedded wiring layer 4 may be disposed in a region of the first encapsulation layer 8 corresponding to the second window. Further, in order to ensure smooth progress of electroplating, before the photoresist layer 16 is formed, a copper seed layer may be formed on the first encapsulation layer 8.

At step S120, a second encapsulation layer covering the first encapsulation layer and the embedded wiring layer is formed, where an accommodation cavity is formed in a region of the second encapsulation layer corresponding to the chip.

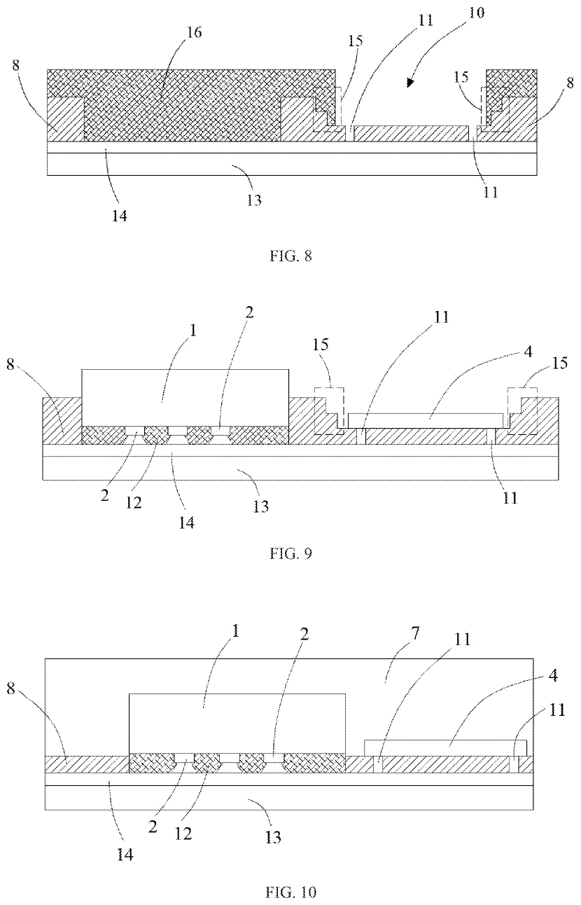

As shown in FIG. 10, the second encapsulation layer 7 may be formed by injection molding, hot pressing or film pressing molding or the like. The second encapsulation layer 7 may also cover the back surface of the chip 1, namely, the accommodation cavity formed in the second encapsulation layer 7 has only one opening end. The second encapsulation layer 7 may also surround the chip 1, namely, the second encapsulation layer 7 only covers the side surface of the chip 1. In other words, an accommodation cavity with two opening ends is formed in the second encapsulation layer 7.

At step S130, the carrier plate is removed, and a fan-out wiring layer is formed on a surface of the first encapsulation layer away from the second encapsulation layer, where the fan-out wiring line is electrically connected to the embedded wiring layer and the pin of the chip.

As shown in FIGS. 11, 12 and 13, the fan-out wiring layer 3 may include spaced a first fan-out line 301 and a second fan-out line 302. In the related arts, when the chip 1 has a large number of pins 2, in order to avoid interleaving or short-circuiting of the fan-out lines connected to the pins 2, the fan-out lines connected to the pins 2 may be stacked, as a result, a thickness of the semiconductor packaging structure is increased. In the present disclosure, the first fan-out line 301 and the second fan-out line 302 may be disposed in a same layer, such that the thickness of the semiconductor packaging structure is reduced. As shown in FIG. 13, for example, the pin 2 include a first pin 201 and a second pin 202, and the fan-out wiring layer 3 may include a first fan-out line 301 and a second fan-out line 302, where the first fan-out line 301 is electrically connected to the embedded line 401 and the first pin 201 of the chip 1, and the second fan-out line 302 is insulated from the first fan-out line 301 and electrically connected to the second pin 202 of the chip 1. The first fan-out line 301 may be plural in number, and the plurality of first fan-out lines 301 are electrically connected to the plurality of first pins 201 of the chip 1 one by one and electrically connected to the plurality of embedded lines 401 one by one. The second fan-out line 302 may be a plural in number, and the plurality of second fan-out lines 302 are electrically connected to the plurality of second pins 202 of the chip 1 one by one. The first fan-out line 301 may be in contact with a region of the embedded line 401 in one via-hole 11, such that the first fan-out line 301 is electrically connected to the embedded line 401. Along a direction perpendicular to the thickness direction of the chip 1, an end of the embedded line 401 close to the chip 1 is electrically connected to the first fan-out line 301, and an end of the embedded line 401 away from the chip 1 is located at a side of the second fan-out line 302 away from the chip 1. Furthermore, the via-hole groups formed in the first encapsulation layer 8 may also be formed after the carrier plate 13 is removed, and a conductive material may be added to the via-holes 11 to facilitate the electrical connection between the first fan-out line 301 and the embedded line 401.

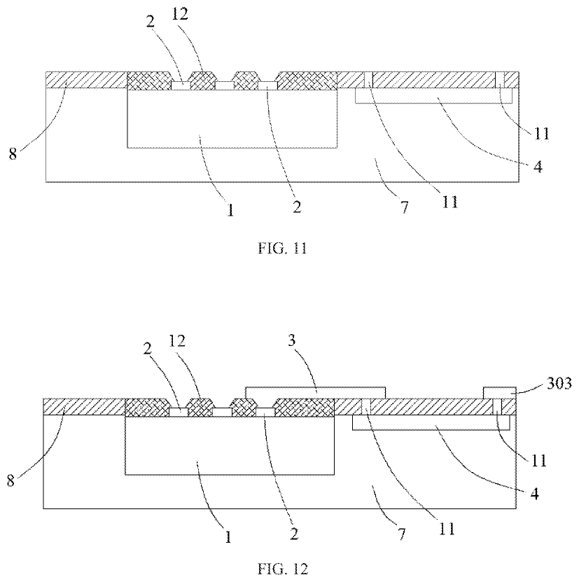

Furthermore, as shown in FIG. 12, the fan-out wiring layer 3 may further include a third fan-out line 303 which is electrically connected with the embedded line 401. The third fan-out line 303 is spaced apart from both the first fan-out line 301 and the second fan-out line 302. For example, when each via-hole group includes two via-holes 11, the first fan-out line 301 is in contact with a region of the embedded line 401 located in one via-hole 11, and the third fan-out line 303 is in contact with a region of the embedded line 401 in the other via-hole 11.

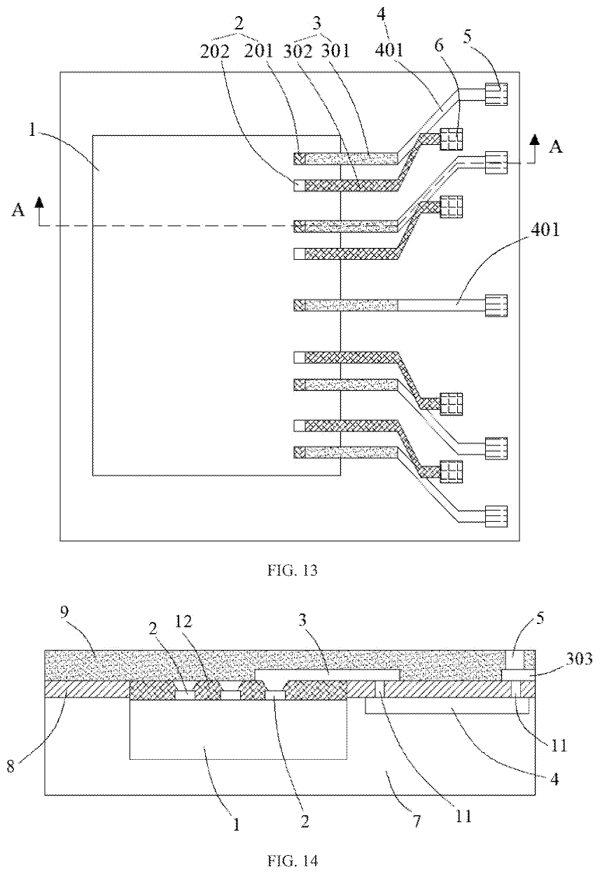

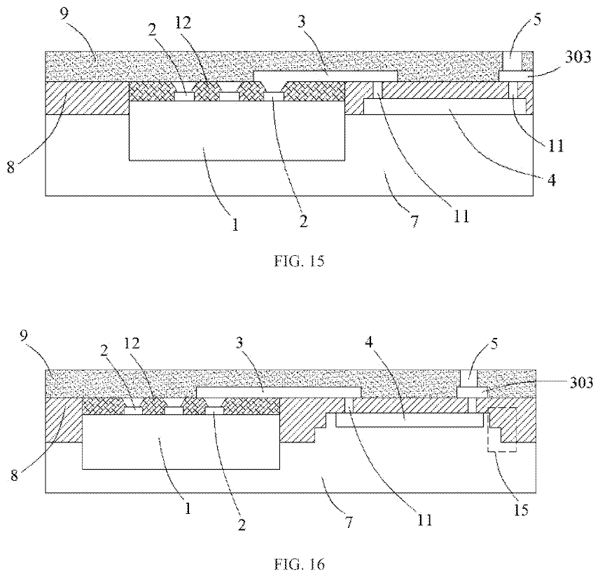

As shown in FIGS. 13 and 14, after the fan-out wiring layer 3 is formed, the semiconductor packaging method of the present disclosure may further include: forming a conductive column layer, where the conductive column layer may include a first conductive column 5 electrically connected to the third fan-out line 303 and a second conductive column 6 electrically connected to the second fan-out line 302. The first conductive column 5 may be disposed on a surface of the third fan-out line 303 away from the second encapsulation layer 7, and the second conductive column 6 may be disposed on a surface of the second fan-out line 302 away from the second encapsulation layer 7. The semiconductor packaging method of the present disclosure may further include: forming a dielectric layer 9 covering the fan-out wiring layer 3 and the first encapsulation layer 8, where the dielectric layer 9 surrounds the first conductive column 5 and the second conductive column 6. An end surface of the first conductive column 5 away from the second encapsulation layer 7 and an end surface of the second conductive column 6 away from the second encapsulation layer 7 are flush with a surface of the dielectric layer 9 away from the second encapsulation layer 7. In an embodiment, along a direction perpendicular to the thickness direction of the chip 1, the first conductive column 5 is located at a side of the second conductive column 6 away from the chip 1. The structure shown in FIG. 14 can be formed based on the structure shown in FIG. 5, namely, the structure shown in FIG. 14 corresponds to the circumstance in which no recess 10 is formed in the embedding region. The structure shown in FIG. 15 can be formed based on the structure shown in FIG. 7, namely, the structure shown in FIG. 15 corresponds to the circumstance in which the recess 10 is formed in the embedding region. The structure shown in FIG. 16 can be formed based on the structure shown in FIG. 9, namely, the structure shown in FIG. 16 corresponds to the circumstance in which the stepped stair structure 15 is formed on the sidewall of the recess 10 formed in the embedding region.

An embodiment of the present disclosure further provides a semiconductor packaging structure, which can be manufactured by the above-mentioned semiconductor packaging method. As shown in FIGS. 14 to 16, the semiconductor packaging structure may include a chip 1, a packaging body, an embedded wiring layer 4 and a fan-out wiring layer 3.

The packaging body packages the chip 1 and further includes a second encapsulation layer 7 and a first encapsulation layer 8 stacked. The embedded wiring layer 4 is disposed between the second encapsulation layer 7 and the first encapsulation layer 8. The fan-out wiring layer 3 is disposed on a surface of the first encapsulation layer 8 away from the second encapsulation layer 7, and electrically connected to the embedded wiring layer 4 and a pin 2 of the chip 1.

An accommodation cavity may be formed on a surface of the second encapsulation layer 7 facing toward the first encapsulation layer 8. The chip 1 may be disposed in the accommodation cavity. A front surface of the chip 1 is away from the accommodation cavity and located outside the accommodation cavity. In other words, the chip 1 is partially protruded out of the accommodation cavity. The embedded wiring layer 4 may be disposed in a region outside the accommodation cavity.

In an embodiment of the present disclosure, a plurality of via-holes 11 may be disposed in the first encapsulation layer 8. The embedded wiring layer 4 may fill the via-holes 11. In another embodiment of the present disclosure, a recess 10 may be provided in the first encapsulation layer 8, and a plurality of via-holes 11 may be provided in a bottom wall of the recess 10. The embedded wiring layer 4 is formed in the recess 10 and the via-holes 11 to fill the recess 10 and the via-holes 11. In another embodiment of the present disclosure, a recess 10 is provided in the first encapsulation layer 8 and a plurality of via-holes 11 are provided in a bottom wall of the recess 10 and further, a stepped stair structure 15 is formed on a sidewall of the recess 10. The embedded wiring layer 4 is formed in the recess 10 and the via-holes 11 to cover the bottom wall of the recess 10 and fill the via-holes 11.

The embedded wiring layer 4 may include an embedded line 401. The fan-out wiring layer 3 may include a first fan-out line 301 and a second fan-out line 302. The first fan-out line 301 is electrically connected to the embedded line 401 and the first pin 201 of the chip 1, and the second fan-out line 302 is insulated from the first fan-out line 301 and electrically connected to the second pin 202 of the chip 1. Along a direction perpendicular to a thickness direction of the chip 1, an end of the embedded line 401 close to the chip 1 is electrically connected to the first fan-out line 301. Alternatively, an orthographic projection of the embedded line 401 on a surface of the first encapsulation layer 8 away from the second encapsulation layer 7 is overlapped with the second fan-out line 302.

The semiconductor packaging structure may further include a dielectric layer 9 and a conductive column layer. The dielectric layer 9 may be disposed at a side of the first encapsulation layer 8 away from the second encapsulation layer 7 and cover the fan-out wiring layer 3. The conductive column layer is at least partially formed in the dielectric layer, and may include a first conductive column 5 and a second conductive column 6. The first conductive column 5 is electrically connected to the embedded line 401, and the second conductive column 6 is electrically connected to the second fan-out line 302. Alternatively, along a direction perpendicular to the thickness direction of the chip 1, the first conductive column 5 is located at a side of the second conducive column 6 away from the chip 1. A material of the first encapsulation layer 8 may include a photosensitive material.

The semiconductor packaging method and the semiconductor packaging structure provided by the embodiments of the present disclosure belong to a same inventive concept, and relevant details and beneficial effects may be referred to each other and will not be repeated herein.

The above descriptions are made merely to preferred embodiments of the present disclosure rather than intended to limit the present disclosure in any manner. Although the present disclosure is made with preferred embodiments as above, these preferred embodiments are not used to limit the present disclosure. Those skilled in the art may make some changes or modifications to the technical contents of the present disclosure as equivalent embodiments without departing from the scope of the technical solution of the present disclosure. Any simple changes, equivalent changes or modifications made to the above embodiments based on the technical essence of the present disclosure without departing from the contents of the technical solution of the present disclosure shall all fall within the scope of protection of the present disclosure.

1. A semiconductor packaging method, comprising:
providing a chip;
forming a first encapsulation layer surrounding the chip;
forming an embedded wiring layer at least on a side of the first encapsulation layer;
forming a second encapsulation layer covering the first encapsulation layer and the embedded wiring layer, wherein an accommodation cavity is formed in a region of the second encapsulation layer corresponding to the chip; and
forming a fan-out wiring layer on a surface of the first encapsulation layer away from the second encapsulation layer, wherein the fan-out wiring layer is electrically connected to the embedded wiring layer and a pin of the chip.

2. The semiconductor packaging method of claim 1, wherein
forming the first encapsulation layer surrounding the chip comprises:
providing a carrier plate, forming the first encapsulation layer on the carrier plate, and attaching the chip onto the first encapsulation layer, wherein the first encapsulation layer surrounds the chip and a back surface of the chip is away from the carrier plate;
forming the embedded wiring layer at least on a side of the first encapsulation layer comprises:
forming the embedded wiring layer at least on a side of the first encapsulation layer away from the carrier plate;
forming the fan-out wiring layer on the surface of the first encapsulation layer away from the second encapsulation layer comprises:
removing the carrier plate, and forming the fan-out wiring layer on the surface of the first encapsulation layer away from the second encapsulation layer.

3. The semiconductor packaging method of claim 1, wherein
the pin of the chip comprises a first pin and a second pin, the embedded wiring layer comprises an embedded line, and the fan-out wiring layer comprises:
a first fan-out line, electrically connected to the embedded line and the first pin of the chip; and
a second fan-out line, insulated from the first fan-out line and electrically connected to the second pin of the chip.

4. The semiconductor packaging method of claim 1, wherein forming the embedded wiring layer at least on a side of the first encapsulation layer comprises:
forming a plurality of via-holes in the first encapsulation layer, and forming the embedded wiring layer at a side of the first encapsulation layer and in the via-holes; or
forming a recess in the first encapsulation layer, forming a plurality of via-holes in a bottom wall of the recess, and forming the embedded wiring layer in the recess and the via-holes to fill the recess and the via-holes; or
forming a recess in the first encapsulation layer, forming a plurality of via-holes in a bottom wall of the recess, forming a stepped stair structure on a sidewall of the recess, and forming the embedded wiring layer in the recess and the via-holes to cover the bottom wall of the recess and fill the via-holes.

5. The semiconductor packaging method of claim 3, wherein the fan-out wiring layer further comprises:
a third fan-out line, disposed on a surface of the first encapsulation layer away from the second encapsulation layer and electrically connected to the embedded line;
the semiconductor packaging method further comprises:
forming a conductive column layer, wherein the conductive column layer comprises a first conductive column and a second conductive column, the first conductive column is disposed on a surface of the third fan-out line away from the second encapsulation layer and electrically connected to the third fan-out line, and the second conductive column is disposed on a surface of the second fan-out line away from the second encapsulation layer and electrically connected to the second fan-out line; and
forming a dielectric layer covering the fan-out wiring layer and the first encapsulation layer, wherein the dielectric layer surrounds the first conductive column and the second conductive column.

6. The semiconductor packaging method of claim 1, wherein forming the first encapsulation layer surrounding the chip comprises:
forming the first encapsulation layer;
forming a first window in the first encapsulation layer; and
disposing the chip in the first window.

7. The semiconductor packaging method of claim 1, wherein forming the embedded wiring layer at least on a side of the first encapsulation layer comprises:
forming a photoresist layer covering the first encapsulation layer; and
patterning the photoresist layer to form a second widow in the photoresist layer, and disposing the embedded wiring layer in a region of the first encapsulation layer corresponding to the second window.

8. A semiconductor packaging structure, comprising:
a chip;
a packaging body, packaging the chip and comprising a first encapsulation layer and a second encapsulation layer stacked;
an embedded wiring layer, disposed between the first encapsulation layer and the second encapsulation layer; and
a fan-out wiring layer, disposed on a surface of the first encapsulation layer away from the second encapsulation layer, and electrically connected to the embedded wiring layer and a pin of the chip.

9. The semiconductor packaging structure of claim 8, further comprising: an accommodation cavity formed on a surface of the second encapsulation layer facing toward the first encapsulation layer;
the chip is disposed in the accommodation cavity, and a front surface of the chip is away from the accommodation cavity and located outside the accommodation cavity; and
the embedded wiring layer is disposed in a region outside the accommodation cavity.

10. The semiconductor packaging structure of claim 8[or 9], wherein the pin of the chip comprises a first pin and a second pin, the embedded wiring layer comprises an embedded line, and the fan-out wiring layer comprises:
a first fan-out line, electrically connected to the embedded line and the first pin of the chip; and
a second fan-out line, insulated from the first fan-out line and electrically connected to the second pin of the chip.

11. The semiconductor packaging structure of claim 10, further comprising:
a dielectric layer, disposed at a side of the first encapsulation layer away from the second encapsulation layer, and covering the fan-out wiring layer; and
a conductive column layer, at least partially formed in the dielectric layer, wherein the conductive column layer comprises a first conductive column and a second conductive column, the first conductive column is electrically connected to the embedded line, and the second conductive column is electrically connected to the second fan-out line.

12. The semiconductor packaging structure of claim 8, wherein
a plurality of via-holes are provided in the first encapsulation layer, and the embedded wiring layer fills the via-holes; or,
a recess is provided in the first encapsulation layer, a plurality of via-holes are provided in a bottom wall of the recess, and the embedded wiring layer is formed in the recess and the via-holes to fill the recess and the via-holes; or,
a recess is provided in the first encapsulation layer, a plurality of via-holes are provided in a bottom wall of the recess, and a stepped stair structure is provided in a sidewall of the recess; the embedded wiring layer is formed in the recess and the via-holes to cover the bottom wall of the recess and fill the via-holes.

13. The semiconductor packaging structure of claim 8, wherein a material of the first encapsulation layer comprises a photosensitive material.

14. The semiconductor packaging structure of claim 10, wherein the first fan-out line and the second fan-out line are disposed in a same layer.

15. The semiconductor packaging structure of claim 11, wherein the fan-out wiring layer further comprises a third fan-out line, which is disposed on a surface of the first encapsulation layer away from the second encapsulation layer and electrically connected to the embedded line and the first conductive column.

16. The semiconductor packaging structure of claim 8, wherein a first window is formed in the first encapsulation layer, and the chip is disposed in the first window.

17. The semiconductor packaging structure of claim 8, further comprising a photoresist layer covering the first encapsulation layer, and a second widow is formed in the photoresist layer by patterning the photoresist layer, and the embedded wiring layer is disposed in a region of the first encapsulation layer corresponding to the second window.

18. The semiconductor packaging structure of claim 8, further comprising a protective layer, which is provided in a front surface of the chip.
